(19) United States
(12) Patent Application Publication
(10) Pub. No.: US 2019/0379397 A1
(43) Pub. Date: Dec. 12, 2019

(54) ARCHITECTURE FOR HIGH-SPEED COMPUTATION OF ERROR-DETECTING CRC CODES OF DATA PACKETS TRANSFERRED VIA DIRECTLY CONNECTED BUS

(71) Applicant: CESNET, zajmove sdruzeni pravnickych osob, Praha 6 (CZ)

(72) Inventors: Lukas KEKELY, Praha 6 (CZ); Jakub CABAL, Praha 6 (CZ)

(73) Assignee: CESNET, zajmove sdruzeni pravnickych osob, Praha 6 (CZ)

(21) Appl. No.: 16/433,672

(22) Filed: Jun. 6, 2019

(30) Foreign Application Priority Data
Jun. 6, 2018 (CZ) PV 2018-270

(51) Int. Cl. H03M 13/09; H04L 1/00; G06F 11/10; G06F 17/50

(52) U.S. Cl. CPC H03M 13/091; G06F 17/5054; G06F 11/1004; H04L 1/0061

(57) ABSTRACT

Architecture in which a data bus is by its data outputs is interconnected with N parallel submodules (9 or 19) specialized to compute CRC values from given parts of data bus word (9.1 or 19.1), the number of which (N) is given by the maximal number of data packets transferred in a single data bus word; a unique form of intermediate CRC values distribution between submodules (9) through signals (9.2, 9.4) and register (10) in serial version of top-level architecture or between submodules (19) through signals (19.2, 19.4, 19.5, 19.6) and register (20) in parallel version of the top-level architecture, where the internal structure of individual submodules (9 or 19) is specifically tailored for such an arrangement; and a structure of each submodule (9 or 19) capable of processing one part of data bus word separates the main CRC value computation is disclosed.

### BACKGROUND OF THE INVENTION

The proposed solution deals primarily with the processing of data packets in Ethernet-based computer networks, however, it is general enough to be also utilizable for a vast area of different data transfer mechanisms which use some kind of CRC value to ensure data integrity (e.g. high-bandwidth memory technology). During transfer over a medium, the data are susceptible to the introduction of random bit errors or burst errors, which must be usually detected before further processing. Damaged data should be then ignored as their origin meaning (semantics) can be significantly altered by the introduced errors. Therefore, the solution falls into the area of data transfers, telecommunication technology, and services.

### INDEX TO ABBREVIATIONS

CRC—cyclic redundancy check
FPGA—field-programmable gate array

### HBM—High Bandwidth Memory

### HMC—Hybrid Memory Cube

### CURRENT STATE OF THE ART

To ensure the integrity of variably long data packets during transfer over a medium, the CRC control code value is computed and appended before their transmission. After transfer of the packets and their reception by the other communicating side, a new CRC value is computed from the received data. The computed value is then compared with the value appended to the packet by the sender. Equality of both CRC values signifies transmission of data without any error. On the other hand, if CRC values are not equal, the data have been somehow altered on the way and received message is invalid. Independent CRC value must be computed for each transferred packet (transaction) based only on data it contains.

Current solutions are able to realize basic CRC computations with relatively high theoretical throughputs. However, their main shortcoming is in the missing support for parallel computation of values for multiple individual packets transferred simultaneously (i.e. sharing a single data bus word). This considerably limits the real achievable throughput of these solutions, especially when very short packets are processed. The negative impact of the described shortcoming is becoming worse as data buses are constantly getting wider with their rising throughput requirements. Insufficient achievable throughput of CRC computation over data packets can therefore significantly limit the total transfer speed of the whole communication.

### SUMMARY OF THE INVENTION

The throughput disadvantages mentioned above are eliminated by the Architecture for High-speed Computation of Error-detecting CRC Codes of Data Packets Transferred via Directly Connected Bus, according to the presented solution. Its principle is that the data bus word is divided between multiple (a total of N) individual submodules for CRC value computation from transferred packets. The number of these submodules is given by the data bus width, or more specifically by the maximal possible number of finished packets in a single data word on this bus. Every submodule is capable of CRC value computation based on the given part of the data word and intermediate CRC values computed by previous submodules. The internal architecture of each submodule enables correct CRC computation for every valid situation that can occur in the processed data word part. In the case of the packet start, the data before the packet are masked on the data input of the submodule. Furthermore, if the end of the same packet is also in the same data word part, a multiplexer forwards the masked data input to a specific CRC end handling logic and resulting CRC value is provided on the output. On the other hand, in the case of ending packet that continues from previous word parts, the unaltered input data are used together with intermediate CRC values from previous submodules and finalized CRC values is provided on the output. If starting packet is not ending in the same word part, the masked input data are used to compute intermediate CRC value and it is provided for the subsequent submodules. Finally, if the processed data word part does not contain packet start nor packet end, the unaltered input data are used to compute base CRC value which is then accumulated with the intermediate values from the previous submodule and the resulting intermediate CRC value is again provided for the next submodules. The behaviour of each submodule is controlled only by the signaling of packet positions that is a part of the connected input data bus.

In a preferred embodiment, the described architecture is created within an FPGA chip, which serves to receive, process and send data packets on Ethernet-based computer networks or high-bandwidth memories (HBM). The architecture is usually placed on the chip in two identical an independent instances for each communication port—one instance for transmitting (TX) side (appending of CRC value to the packet) and the other instance for receiving (RX) side (comparison of CRC values).

The advantage of the proposed solution is maintaining a very high throughput of CRC computation when processing packets of arbitrary valid lengths, so even for the shortest possible ones. Multiple independent CRC values can be computed in every cycle of FPGA clock as the processing of the data bus is divided between multiple submodules, which are able to cooperate together on a long packet or independently handle multiple short ones. Another advantage of the solution is the ability to fine-tune the architecture to the specific parameters of particular data bus and packets transferred over it. The submodules for the CRC computation are connected in a homogenous manner and share a unified interface, therefore the alteration of the top-level circuit structure is not a problem.

### EXPLANATION OF THE DRAWINGS

The principle of the proposed solution is further explained and described using the attached drawings. The architecture of the solution has two versions of realization—serial and parallel.

FIG. 1 shows the block diagram of the serial version of basic CRC computation submodule and

FIG. 2 then shows an example of the serial connection of multiple of these submodules into a working top-level architecture.

FIG. 3 shows the block diagram of the parallel version of basic CRC computation submodule and

FIG. 4 then shows an example of the parallel connection of multiple of these submodules into a working top-level architecture.

### DETAILED DESCRIPTION OF THE PREFERRED EMBODIMENTS

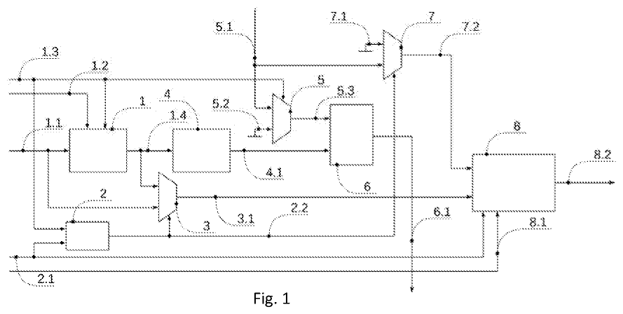

The subjects of the new solution, in general, are two versions of circuit architecture for the high-speed computation of cyclic redundancy check (CRC) codes that can handle multiple (up to N) data packets in every single clock cycle when processing a wide directly connected data transfer bus. The whole functionality of the circuit is divided into N submodules, where the attached FIG. 1 shows the circuit solution of the serial version of one of these submodules.

The diagram presented in the FIG. 1 contains component 1, which alters the input data of width R_{w} associated with this submodule to ensure correct initialization of CRC computation process from packet start, which can occur on different positions in the word. Component 1 is connected directly to the data word of the bus transferring packets 1.1, signal 1.2 to determine packet start exact position, flag 1.3 to determine the validity of the packet start in given data word part, and provides correctly masked data output 1.4. Alteration of data by component 1 from its input 1.1 to output 1.4 ensures the independence of the following CRC computations on the data symbols that are transferred on the bus before the actual packet. In other words, any data before the packet are correctly neutralized and ignored for the following computations. Component 2 chooses between continuing or finishing the CRC computation in the current data word part. Its input flag 1.3 denotes the start of a new packet in this word part, input flag) denotes validity of a packet end, and input flag 2.2 determines the continuation of a packet from the previous word piece processed by the previous submodule. Signal 2.2 is used to control the multiplexer 3, which selects between original input data 1.1 for continuing packets from the previous submodule (clock cycle) or masked input data 1.4 for finalized CRC value computation of a packet wholly contained in the current word part 1.1. Circuit for basic CRC computation 4 puts a CRC value of the whole input data piece 1.4 to its output 4.1. All these computations in component 4 are performed without any regard to packet starts or ends, correct handling of these is left for other components of the architecture like component 1 transforming data 1.1 to 1.4. Multiplexer 5 is controlled by the start of packet flag 1.3 and select between input 5.1 with intermediate CRC value for continuing packets computed in the previous submodule and input 5.2 with initialization CRC value for starting a brand new packet processing. Component 6 aggregates together CRC value 4.1 computed from the data word part of this submodule and CRC value from the output of the described multiplexer 5.3. The created output signal 6.1 is the intermediate CRC value from the last start of packet, detected in this or any previous submodules, up to the end of the current data word part. Multiplexer 7 is controlled by signal 2.2, if there is a packet continuing from the previous submodule into the current data word part, multiplexer 7 selects input signal 5.1 with the intermediate CRC value computed for the previous parts of the continuing packet, in other cases, input signal 7.1 with initialization CRC value is selected. The output 7.2 of the described multiplexer is connected with component 8, which implements finalization of CRC value for packets ending in the current part of the data word. Component 8 further uses data input signal 3.1, output enable flag 2.1, the input signal 8.1 with the exact end of packet position, and creates the output 8.2 with the finalized computed CRC value for any packets ending in this part of the data bus word.

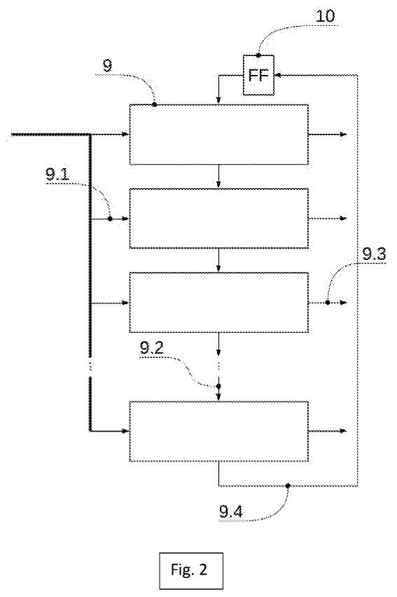

Circuit connection at FIG. 2 depicts an example of an arrangement of N serial submodules 9 from FIG. 1 and the previous description. Every submodule 9 is connected to an input 9.1 from the data bus, which includes control signals and flags for packet boundaries positionings connected to inputs 1.2, 1.3, 1.4, 2.1, 8.1 of the submodule together with data word part of width R_{w} connected to 1.1. Total width of data bus word is, therefore, given as D_{w}=N*R_{w}. Input 9.2 connected to signal 5.1 of every submodule 9 carries the intermediate CRC value from the previous submodule 9 in a sequence. Output 9.3 connected from 8.2 is used for finalized CRC value for packets ending in the given data word part. Finally, output 9.4 connected from 6.1 carries the intermediate CRC values for the next submodule 9 in the sequence. In the case of the N-th (last) submodule 9, the output 9A is connected to the register 10, which stores the intermediate CRC value to the next clock cycle. The output of the register 10 is then used as an input 9.2 of the first submodule 9 in the sequence. This way, the computation can correctly continue even for packets spanning over multiple data bus words.

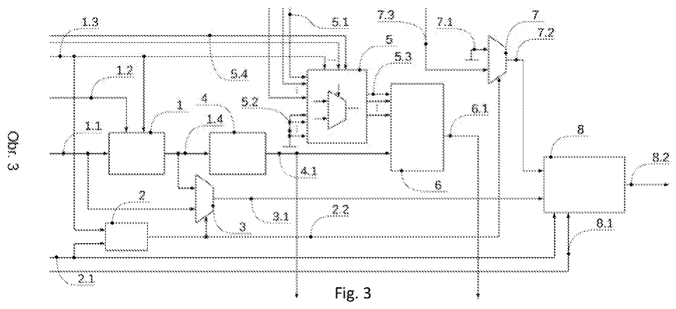

Circuit connection in FIG. 3 shows the parallel version of the submodule from FIG. 1. Most of the connections and component inside the parallel submodule remain the same as in the serial version. However, unlike in FIG. 1, the output of the parallel submodule is also signal 4.1. Multiplexer 5 is also placed M-times, where M is the position (order) of the submodule in the sequence from the top-level architecture. The first inputs 5.1 of multiplexers 5 are connected with all of the computed intermediate CRC values from individual previous data word parts (submodules). Second data inputs 5.2 of multiplexers 5 are connected with the initialization CRC value. Every multiplexer 5 is controlled by an appropriate signal 5.4, which denotes existences of packet starts in the given parts of the data word. M outputs 5.3 from multiplexers 5 are connected to the inputs of component 6, which now aggregates all M intermediate CRC values from the previous data word parts with the CRC value 4.1 computed for the current data word part. Component 6 creates the output 6.1 connected to the output of the whole submodule circuit. Multiplexer 7 is controlled by signal 2.2, if there is a packet continuing from the previous submodule into the current data word part, multiplexer 7 selects input signal 7.3 with the intermediate CRC value computed for the previous parts of the continuing packet, which is sourced from the 6.1 signal of the previous parallel submodule. In other cases, the input signal 7.1 with initialization CRC value is selected by the multiplexer 7. The output signal 7.2 is again connected to component 8 as in the serial version, where 8 realizes the finalization of CRC value for any packets ending in this part of the data bus word.

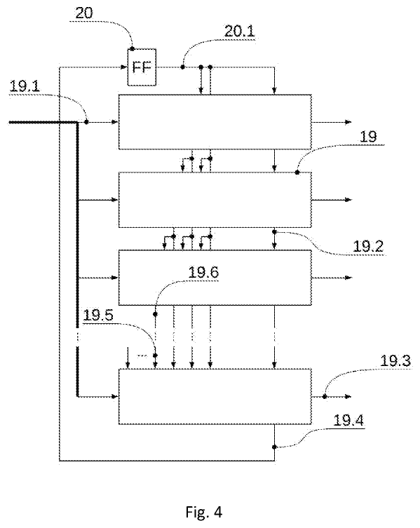

Circuit connection at FIG. 4 depicts an example of an arrangement of N parallel submodules 19 from FIG. 3 and the previous description. Every submodule 19 is connected to an input 19.1 from the data bus, which includes control signals and flags for packet boundaries positionings connected to inputs 1.2, 1.3, 2.1, 5.4, 8.1 of the submodule together with data word part of width R_{w} connected to 1.1. Therefore, connections to the data bus as well as the total data bus width remain the same in the parallel version compared to the serial version, changes are present only in the connection and distribution of the intermediate CRC values between individual submodules. Input 19.2 connected to signal 7.3 carries the intermediate CRC value from the previous submodule 19 in a sequence and, unlike the serial version, in the parallel version this intermediate value is used only for the finalization of CRC for the ending packets, which is provided at the output 19.3 connected from signal 8.2. Finally, output 19.4 connected from 6.1 carries the intermediate CRC values for the next submodule 19 in the sequence. In the case of the N-th (last) submodule 19, the output 19.4 is connected to the register 20, which stores the intermediate CRC value to the next clock cycle. The output 20.1 of the register 20 is then used as an input 19.2 of the first submodule 19 in the sequence and also as the first from M inputs 19.5 of every submodule 19. This way, the computation can correctly continue even for packets spanning over multiple data bus words. Unlike in the serial version, the parallel submodule 19 has the output 19.6 connected from 4.1, which carries the intermediate CRC value computed only from a single given part of the data bus word. Every output 19.6 is then connected to one of the M inputs 19.5 of every subsequent submodule 19.

### INDUSTRIAL APPLICABILITY

Architecture for High-speed Computation of Error-detecting CRC Codes of Data Packets Transferred via Directly Connected Bus according to the presented solution can find industrial applicability in circuits for stream or batch processing of data that are divided into smaller independent pieces called packets or transactions. When compared to commonly applied solutions it allows parallel processing of multiple of these data packets in a single clock cycle (single data bus word), thus considerably increasing the effective achievable throughput of data integrity checking even for very wide data buses.

### CONCLUSION

The solution disclosed above deals with the problem of high-speed computation of error-detecting CRC codes of data packets by means of architecture connected directly to the data bus, where firstly the data bus is by its data outputs interconnected with N parallel submodules (9 or 19) specialized to compute CRC values from given parts of data bus word (9.1 or 19.1), the number of which (N) is given by the maximal number of data packets transferred in a single data bus word; secondly the unique form of intermediate CRC values distribution is realized between submodules (9) through signals (9.2, 9.4) and register (10) in serial version of top-level architecture or between submodules (19) through signals (19.2, 19.4, 19.5, 19.6) and register (20) in parallel version of the top-level architecture, where the internal structure of individual submodules (9 or 19) is specifically tailored for such an arrangement; and finally the structure of each submodule (9 or 19) capable of processing one part of data bus word separates the main CRC value computation without any regard to packet boundaries (4) from the specific alterations of this process required to correctly handle continuing, starting or ending data packets, which is realized independently mainly by component (1) connected to data and control signals of the input data bus (1.1, 1.2, 1.3) for handling packet starts, component (8) connected to masked data signal (3.1) and intermediate CRC values (7.2) through multiplexers (3, 7) controlled by output (2.2) of component (2) for handling packet ends, and by component (6) together with multiplexers (5) handling the correct aggregation and distribution of intermediate CRC values (4.1, 5.1, 5.4, 6.1) for each submodule (9 or 19). Altogether, such parallel arrangement of submodules enables finalization of independent CRC values (9.3 or 19.3) for multiple (up to N) data packets that are simultaneously ending in the same single word of the connected data bus.

What is claimed is:

1. Architecture for High-speed Computation of Error-detecting CRC Codes of Data Packets Transferred via Directly Connected Bus characterized by the fact that firstly the data bus is by its data outputs interconnected with N parallel submodules (9 or 19) specialized to compute CRC values from given parts of data bus word (9.1 or 19.1), the number of which (N) is given by the maximal number of data packets transferred in a single data bus word; secondly the unique form of intermediate CRC values distribution is realized between submodules (9) through signals (9.2, 9.4) and register (10) in serial version of top-level architecture or between submodules (19) through signals (19.2, 19.4, 19.5, 19.6) and register (20) in parallel version of the top-level architecture, where the internal structure of individual submodules (9 or 19) is specifically tailored for such an arrangement; and finally the structure of each submodule (9 or 19) capable of processing one part of data bus word separates the main CRC value computation without any regard to packet boundaries (4) from the specific alterations of this process required to correctly handle continuing, starting or ending data packets, which is realized independently mainly by component (1) connected to data and control signals of the input data bus (1.1, 1.2, 1.3) for handling packet starts, component (8) connected to masked data signal (3.1) and intermediate CRC values (7.2) through multiplexers (3, 7) controlled by output (2.2) of component (2) for handling packet ends, and by component (6) together with multiplexers (5) handling the correct aggregation and distribution of intermediate CRC values (4.1, 5.1, 5.4, 6.1) for each submodule (9 or 19); where such parallel arrangement of submodules enables finalization of independent CRC values (9.3 or 19.3) for multiple (up to N) data packets that are simultaneously ending in the same single word of the connected data bus.

2. The connection according to claim 1 characterized by the fact that it is created within the FPGA based chip or circuit.

3. The connection according to claim 1 characterized by the fact that it is used for CRC values computation or control in the processing of computer network packets.

4. The connection according to claim 1 characterized by the fact that it is created for CRC values computation and control in communication with high-bandwidth memories.
